(19) United States
(12) Patent Application Publication
(10) Pub. No.: US 2009/0032972 A1
(43) Pub. Date: Feb. 5, 2009

(54) SEMICONDUCTOR DEVICE

(75) Inventors: Tadanobu OKUBO, Yokkaichi-shi (JP); Masashi Noda, Ichinomiya-shi (JP); Ryoji Matsushima, Yokkaichi-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/057,914

(22) Filed: Mar. 28, 2008

(30) Foreign Application Priority Data
Mar. 30, 2007 (JP) 2007-092767
Dec. 20, 2007 (JP) 2007-328256

(51) Int. Cl. H01L 23/28

(52) U.S. Cl. 257/777; 257/E23.116

(57) ABSTRACT

A stacked-type semiconductor device includes a plurality of semiconductor elements stacked on a wiring board. Electrode pads of these semiconductor elements are electrically connected to connection pads of the wiring board via metal wires respectively. The long-looped metal wires connected to the upper semiconductor element are fixed by a wire fixing resin portion to the short-looped metal wires connected to the lower semiconductor element. The wire fixing resin portion is filled at least between the metal wires. The stacked semiconductor elements are sealed by a sealing resin layer together with the metal wires.

### CROSS-REFERENCE TO RELATED APPLICATIONS

This application is based upon and claims the benefit of priority from the prior Japanese Patent Application No. 2007-092767, filed on Mar. 30, 2007 and Japanese Patent Application No. 2007-328256, filed on Dec. 20, 2007; the entire contents of which are incorporated herein by reference.

### BACKGROUND OF THE INVENTION

1. Field of the Invention

The present invention relates to a semiconductor device.

2. Description of the Related Art

For realizing a larger capacity and a higher function of a semiconductor device such as a semiconductor memory device, to pack a plurality of stacked semiconductor elements in one package has become a mainstream structure. A trend is toward the increased number of the semiconductor elements packed in one package. Further, many more kinds of the semiconductor elements such as NAND flash memories, DRAM, controllers, and logic elements have come to be used. In accordance with the diversification of the kind of the semiconductor elements, the shape of the elements has also come to be diversified.

The plural semiconductor elements constituting the semiconductor device are stacked in sequence on a wiring board via adhesive layers. As the adhesive layers, adhesive films are generally used. Wire bonding is adopted when the semiconductor elements mounted on the wiring board is electrically connected to the wiring board. Electrode pads of the semiconductor elements and connection pads of the wiring board are electrically connected via metal wires (bonding wires). As a result of resin-sealing such a stack, a stacked-type semiconductor package (stacked semiconductor device) is formed.

In a stacked-type semiconductor package, various problems have been arising in accordance with the increase in the number of the elements packed therein, the miniaturization and diversification of the element shape, and so on. For example, in a case where the stacked structure is adopted for a semiconductor memory device, on one memory element or on multiple stacked memory elements, a controller element smaller than the memory element(s) is stacked (see JP-A 2001-217383 (KOKAI)). Metal wires connected to the small controller element stacked on the large memory element form long loops. The metal wire itself tends to be thinner as the pad area of the semiconductor element becomes smaller.

When a stack of semiconductor elements different in shape is resin-sealed, the long-looped metal wires connected to the small semiconductor element positioned on the upper layer are displaced (wire sweep), and consequently, a short circuit and the like often occur due to the contact between wires. Further, the number of bonding wires increases in a semiconductor package housing a semiconductor element having many pads, such as a controller element or a DRAM. In accordance with an increase in the number of stacked semiconductor elements, the height of loops of the metal wires needs to be lowered. Because of these reasons, gaps between the metal wires and the semiconductor elements and gaps between the metal wires become narrower. In such a case, if common sealing resin is used, due to the influence of its conductive filler such as carbon, leakage may possibly occur between the metal wires and between the metal wires and the semiconductor element.

JP-A 10-074786 (KOKAI) describes that, in wire-bonding a plurality of rows of electrode pads provided on one semiconductor element to a lead frame, the loop height of metal wires connected to electrode pads formed on an inner side of the semiconductor element is made larger, and insulating films are interposed between these metal wires different in height. However, the insulating films have a great limit because of their poor installability into gaps between the metal wires. Further, with the insulating films, it is difficult to prevent the contact between the metal wires connected to the electrode pads in the same row.

Japanese Patent No. 3218816 describes that, in wire-bonding electrode pads of a semiconductor element to a lead frame, metal wires are coupled to one another in a traverse direction via insulative reinforcing materials. Here, resin films or a cured matter of liquid resin is used as the insulative reinforcing materials. However, the liquid resin, even if simply applied on the metal wires, drips off and thus cannot sufficiently couple and reinforce the metal wires. As a solution to this problem, Japanese Patent No. 3218816 describes that glass fiber or the like is blended in the liquid resin. This increases the thickness of the reinforcing resin, which may possibly be an obstacle to the thinning and the like of the package.

JP-A2002-368029 (KOKAI) describes that, in order to prevent a short circuit between metal wires caused by wire sweep at the time of resin sealing, pasted insulating resin is applied on adjacent metal wires after a semiconductor element mounted on a lead frame and the lead are wire-bonded, and the insulating resin is cured to fix the metal wires to each other. Here, the leakage between the metal wires due to the influence of conductive filler in the sealing resin is not taken into consideration. In particular, no measure is taken against the leakage between the metal wires and the semiconductor element ascribable to the decreased loop height.

Further, in accordance with the diversification of the element shape, it is sometimes unavoidable that an outer peripheral portion of an upper semiconductor element among plural stacked semiconductor elements overhangs in a visor form. An area under the visor-shaped overhanging outer peripheral portion of the semiconductor element becomes hollow. It is difficult to completely fill up such a hollow portion with the sealing resin. In particular, in a case where a large number of metal wires are disposed at narrow pitches, the state of an area under the metal wires is like the inside of a spider-webbed tunnel, resulting in low filling performance of the sealing resin. Air in portions left unfilled with the sealing resin (voids) expands in a high-temperature atmosphere at the time of solder connection of the semiconductor device, leading to the occurrence of a defect such as a crack in the semiconductor device.

As an art to prevent a crack and breakage that may occur at the time of the wire bonding of the visor-shaped overhanging portion of the upper semiconductor element, JP-A 2000-277559 (KOKAI) and JP-A 2005-340415 (KOKAI) describe that liquid resin is applied in a space between the overhanging portion of the upper semiconductor element and a wiring board and a gap between a lower semiconductor element and the upper semiconductor element, and this liquid resin is cured to be formed into a support member. However, the generation of the portions left unfilled with the sealing resin (voids) ascribable to the narrowed pitch of the metal wires and accompanying occurrence of a crack are not taken into consideration here.

Stacking a small semiconductor element such as a controller element on a relatively large semiconductor element such as a memory element often has a problem of a filling rate difference at the time of molding of the sealing resin. That is, since a large level difference is generated due to the existence of the upper semiconductor element, a difference in filling time of the resin streams is liable to occur. Consequently, the resin streams let air in, resulting in the generation of the voids. The voids become not only a cause of the aforesaid crack but also a cause of reducing the thickness of the resin covering a top of the semiconductor element. Laser marking on the sealing resin portion which becomes thin due to the voids might damage the semiconductor element because a laser beam penetrates through the resin.

Further, if the small semiconductor element such as the controller element is wire-bonded, load and ultrasonic vibration applied at the time of the bonding are absorbed by an adhesive layer, resulting in a decrease in connection strength of the metal wires. In particular, as for the small semiconductor element, not only the adhesive layer absorbs the load and the ultrasonic vibration, but also the semiconductor element itself is moved by the ultrasonic vibration at the time of the bonding and thus the ultrasonic vibration is further easily absorbed. Therefore, the metal wires cannot have necessary connection strength, which poses problems of a connection failure and lowered reliability.

### SUMMARY OF THE INVENTION

A semiconductor device according to a first aspect of the present invention includes: a wiring board having an element mounting portion and connection pads; a first semiconductor element, mounted on the element mounting portion of the wiring board, having first electrode pads arranged along at least one outer side of the first semiconductor element; a second semiconductor element, stacked on the first semiconductor element, having second electrode pads arranged along at least one outer side of the second semiconductor element positioned near the outer side of the first semiconductor element; first metal wires electrically connecting the connection pads and the first electrode pads; second metal wires electrically connecting the connection pads and the second electrode pads, the second metal wires wiring in the same direction as the first metal wires; a wire fixing resin portion filled between the first metal wires and the second metal wires to fix the second metal wires; and a sealing resin layer formed on the wiring board to seal the first and second semiconductor elements together with the first and second metal wires.

A semiconductor device according to a second aspect of the present invention includes: a wiring board having an element mounting portion and connection pads; a first semiconductor element, mounted on the element mounting portion of the wiring board, having first electrode pads arranged along at least one outer side of the first semiconductor element; a second semiconductor element, stacked on the first semiconductor element, having second electrode pads arranged along at least one outer side of the second semiconductor element; a third semiconductor element, stacked on the second semiconductor element, having third electrode pads arranged along at least one outer side of the third semiconductor element positioned near the outer side of the second semiconductor element; first metal wires electrically connecting the connection pads and the first electrode pads; second metal wires electrically connecting the connection pads and the second electrode pads; third metal wires electrically connecting the connection pads and the third electrode pads, the third metal wires wiring in the same direction as the second metal wires; a wire fixing resin portion filled between the second metal wires and the third metal wires to fix the second and third metal wires; and a sealing resin layer formed on the wiring board to seal the first, second, and third semiconductor elements together with the first, second, and third metal wires.

A semiconductor device according to a third aspect of the present invention includes: a wiring board having an element mounting portion and connection pads; a semiconductor element, disposed above the element mounting portion of the wiring board, having electrode pads arranged along at least one outer side of the semiconductor element; metal wires electrically connecting the connection pads and the electrode pads; an insulating resin portion having a cured matter of liquid resin applied to cover end portions of the metal wires connected to the semiconductor element; and a sealing resin layer formed on the wiring board to seal the semiconductor element together with the metal wires.

A semiconductor device according to a fourth aspect of the present invention includes: a wiring board having an element mounting portion and connection pads; a first semiconductor element, mounted on the element mounting portion of the wiring board, having first electrode pads arranged along at least one outer side of the first semiconductor element; a second semiconductor element, stacked on the first semiconductor element, having second electrode pads arranged along at least one outer side of the second semiconductor element, at least part of an outer peripheral portion of the second semiconductor element protruding in a visor shape; first metal wires electrically connecting the connection pads and the first electrode pads; second metal wires electrically connecting the connection pads and the second electrode pads; a filling resin portion having a cured matter of liquid resin which is filled in a hollow portion existing under the visor-shaped protruding portion of the second semiconductor element; and a sealing resin layer formed on the wiring board to seal the first and second semiconductor elements together with the first and second metal wires.

A semiconductor device according to a fifth aspect of the present invention includes: a wiring board having an element mounting portion and connection pads; a first semiconductor element, mounted on the element mounting portion of the wiring board, having first electrode pads arranged along at least one outer side of the first semiconductor element; a second semiconductor element, stacked on the first semiconductor element, having second electrode pads arranged along at least one outer side of the second semiconductor element, the second semiconductor element being smaller than the first semiconductor element; a buried resin portion having a cured matter of liquid resin applied on a surface region of the first semiconductor element excluding a region on which the second semiconductor element is stacked; first metal wires electrically connecting the connection pads and the first electrode pads; second metal wires electrically connecting the connection pads and the second electrode pads; and a sealing resin layer formed on the wiring board to seal the first and second semiconductor elements together with the first and second metal wires.

A semiconductor device according to a sixth aspect of the present invention includes: a wiring board having an element mounting portion and connection pads; a first semiconductor element, bonded on the element mounting portion of the wiring board via a first adhesive layer, having first electrode pads arranged along at least one outer side of the first semiconductor element; a second semiconductor element, bonded on the first semiconductor element via a second adhesive layer, having second electrode pads arranged along at least one outer side of the second semiconductor element; an element fixing resin portion formed along an outer peripheral portion including an outer side of the second semiconductor element excluding the outer side along which the second electrode pads is arranged, to fix the second semiconductor element; first metal wires electrically connecting the connection pads and the first electrode pads; second metal wires electrically connecting the connection pads and the second electrode pads; a sealing resin layer formed on the wiring board to seal the first and second semiconductor elements together with the first and second metal wires.

### BRIEF DESCRIPTION OF THE DRAWINGS

FIG. 1 is a plane view of a semiconductor device according to a first embodiment.

FIG. 2 is a cross-sectional view of the semiconductor device shown in FIG. 1.

FIG. 3 is a plane view showing a modified example of the semiconductor device shown in FIG. 1.

FIG. 4 is across-sectional view of the semiconductor device shown in FIG. 3.

FIG. 5 is a plane view showing another modified example of the semiconductor device shown in FIG. 1.

FIG. 6 is across-sectional view of the semiconductor device shown in FIG. 5.

FIG. 7 is a plane view of a semiconductor device according to a second embodiment.

FIG. 8 is a cross-sectional view of the semiconductor device shown in FIG. 7.

FIG. 9 is a plane view showing a modified example of the semiconductor device shown in FIG. 7.

FIG. 10 is a cross-sectional view of the semiconductor device shown in FIG. 9.

FIG. 11 is a plane view showing another modified example of the semiconductor device shown in FIG. 7.

FIG. 12 is a cross-sectional view of the semiconductor device shown in FIG. 11.

FIG. 13 is a plane view of a semiconductor device according to a third embodiment.

FIG. 14 is a cross-sectional view of the semiconductor device shown in FIG. 13.

FIG. 15 is an enlarged partial cross-sectional view of the semiconductor device shown in FIG. 13.

FIG. 16 is another enlarged partial cross-sectional view of the semiconductor device shown in FIG. 13.

FIG. 17 is a plane view showing a modified example of the semiconductor device shown in FIG. 13.

FIG. 18 is a plane view of a semiconductor device according to a fourth embodiment.

FIG. 19 is a cross-sectional view of the semiconductor device shown in FIG. 18.

FIG. 20 is a plane view of a semiconductor device according to a fifth embodiment.

FIG. 21 is a cross-sectional view of the semiconductor device shown in FIG. 20.

FIG. 22 is a plane view showing a modified example of the semiconductor device shown in FIG. 20.

FIG. 23 is a plane view showing another modified example of the semiconductor device shown in FIG. 20.

FIG. 24 is a plane view of another semiconductor device according to the fifth embodiment.

FIG. 25 is a cross-sectional view of the semiconductor device shown in FIG. 24.

FIG. 26 is a plane view of a semiconductor device according to a sixth embodiment.

FIG. 27 is a cross-sectional view of the semiconductor device shown in FIG. 26.

FIG. 28 is a plane view showing a modified example of the semiconductor device shown in FIG. 26.

FIG. 29 is a cross-sectional view of the semiconductor device shown in FIG. 28.

FIG. 30 is a plane view showing another modified example of the semiconductor device shown in FIG. 26.

FIG. 31 is a cross-sectional view of the semiconductor device shown in FIG. 30.

### DETAILED DESCRIPTION OF THE INVENTION

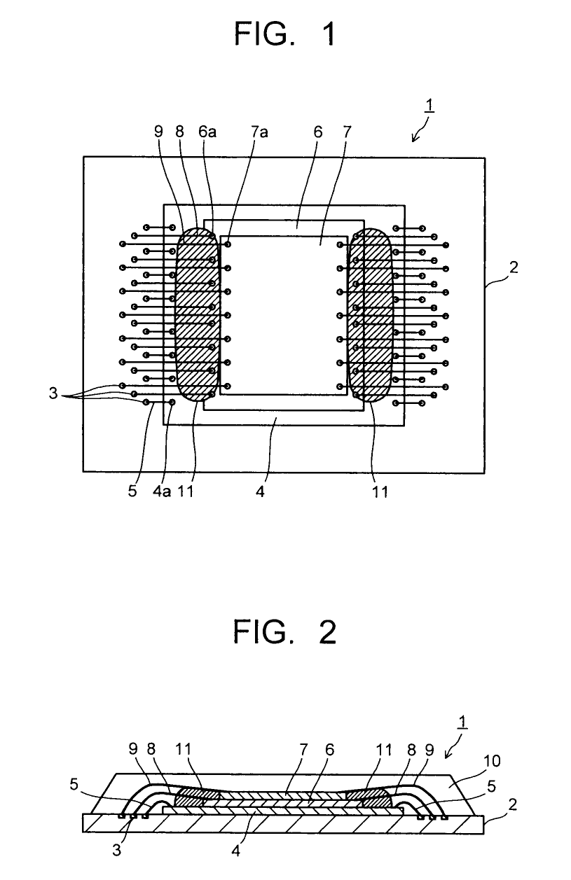

Hereinafter, embodiments for carrying out the present invention will be described. First, a stacked-type semiconductor device according to a first embodiment of the present invention will be described with reference to FIG. 1 and FIG. 2. FIG. 1 is a plane view showing the structure of the semiconductor device according to the first embodiment, and FIG. 2 is its cross-sectional view. The semiconductor device 1 shown in FIG. 1 and FIG. 2 has a wiring board 2 as a circuit base for element mounting. As the wiring board 2, any wiring board may be used, provided that a semiconductor element can be mounted thereon and a wiring network is provided on its surface or in its internal part. As the circuit base, a lead frame or the like can also be employed.

As a substrate forming the wiring board 2, an insulating substrate such as a resin substrate, a ceramic substrate, or a glass substrate, or a semiconductor substrate can be employed. A concrete example of the wiring board 2 is a printed wiring board using glass-epoxy resin, or BT resin (Bismaleimide-triazine resin). External connection terminals (solder bumps or the like), not shown, are provided on a lower surface of the wiring board 2. The wiring board 2 has, on its upper surface, an element mounting portion and connection pads 3 provided around the element mounting portion and electrically connected to the external connection terminals (not shown) via the wiring network (not shown). The connection pads 3 serve as connection portions at the time of wire bonding.

A first semiconductor element 4 is bonded on the element mounting surface (upper surface) of the wring board 2 via an adhesive layer (not shown). The first semiconductor element 4 has first electrode pads 4a which are disposed on the same surface as a surface on which an integrated circuit including transistors is formed. The first electrode pads 4a are electrically connected to the connection pads 3 of the wiring board 2 via first metal wires 5. As the first metal wires 5, commonly used thin metal wires such as Au wires and Cu wires are used. The same applies to the other metal wires. The first semiconductor element 4 is, as a concrete example, a memory element having a relatively large outside dimension, but is not limited to this.

The first electrode pads 4a are arranged in line along two opposed sides among outer sides forming the outline of the first semiconductor element 4. The connection pads 3 of the wiring board 2 are arranged so as to correspond to the respective first electrode pads 4a which are arranged in two rows. The first metal wires 5 are wired from the first electrode pads 4a toward the connection pads 3 or from the connection pads 3 toward the first electrode pads 4a. One-side end portions of the first metal wires 5 are connected to the connection pads 3 and the other end portions are connected to the first electrode pads 4a.

A second semiconductor element 6 is bonded on the first semiconductor element 4 via an adhesive layer (not shown). Further, a third semiconductor element 7 is bonded on the second semiconductor element 6 via an adhesive layer (not shown). The second semiconductor element 6 has second electrode pads 6a disposed on the same surface as a surface on which an integrated circuit including transistors is formed. Similarly, the third semiconductor element 7 has third electrode pads 7a.

The second and third semiconductor elements 6, 7 are stacked on the first semiconductor element 4, their disposition directions being aligned so that the second and third electrode pads 6a, 7a come close to the first electrode pads 4a of the first semiconductor element 4. Specifically, the second electrode pads 6a are arranged in line along two outer sides positioned near the electrode arranged sides (two opposed sides) of the first semiconductor element 4. Similarly, the third electrode pads 7a are arranged in line along two outer sides positioned near the electrode arranged sides (two sides) of the first and second semiconductor elements 4, 6.

Each of the second and third semiconductor elements 6, 7 is, as a concrete example, a controller or the like having a small outside dimension, but is not limited to this. The second semiconductor element 6 is smaller in outside dimension than the first semiconductor element 4. The third semiconductor element 7 is smaller in outside dimension than the second semiconductor element 6. Therefore, the first, second, and third semiconductor elements 4, 6, 7 are stacked with their electrodes pads 4a, 6a, 7a exposed, that is, in a face-up state so that the electrode pads 4a, 6a, 7a are disposed in the same layout and in the same arrangement direction.

The second and third electrode pads 6a, 7a are electrically connected to the connection pads 3 of the wiring board 2 via second and third metal wires 8, 9, similarly to the first electrode pads 4a. The second and third metal wires 8, 9 are wired in the same direction as the first metal wires 5. One-side end portions of the second and third metal wires 8, 9 are connected to the connection pads 3 and the other end portions are connected to the second and third electrode pads 6a, 7a. In this manner, the metal wires (bonding wires) 5, 8, 9 connected to the electrode pads 4a, 6a, 7a are wired in the same direction.

On the wiring board 2 on which the first, second, and third semiconductor elements 4, 6, 7 are mounted, a sealing resin layer 10 made of, for example, epoxy resin is formed by molding. The first, second, and third semiconductor elements 4, 6, 7, and the metal wires 5, 8, 9 are integrally sealed by the sealing resin layer 10. In FIG. 1, the illustration of the sealing resin layer 10 is omitted. FIG. 1 and FIG. 2 show the structure in which the three semiconductor elements 4, 6, 7 are stacked, but the number of the stacked semiconductor elements is not limited to this. The number of the stacked semiconductor elements may be two or may be four or more.

In the structure in which the second and third semiconductor elements 6, 7 are smaller than the first semiconductor element 4, the loops of the second and third metal wires 8, 9 are longer than the loops of the first metal wires 5. Accordingly, the long-looped second and third metal wires 8, 9 are easily displaced by resin streams when the sealing resin layer 10 is formed by, for example, injection molding. That is, wire sweep of the second and third metal wires 8, 9 is liable to occur, which may cause a short circuit.

Therefore, in the first embodiment, liquid resin is applied on the second and third metal wires 8, 9 and thereafter cured, whereby wire fixing resin portions 11 fixing the second and third metal wires 8, 9 are formed. The wire fixing resin portions 11 has a cured matter of the liquid resin. In the semiconductor device 1 shown in FIG. 1 and FIG. 2, the wire fixing resin portions 11 are formed near the end portions, of the metal wires 8, 9, connected to the semiconductor elements 6, 7. The wire fixing resin portions 11 are formed on the metal wires 8, 9 from their element-side end portions to horizontally wired portions (flat portions).

The wire fixing resin portions 11 only need to be filled at least between the second metal wires 8 and the third metal wires 9. In the semiconductor device 1 shown in FIG. 2, the wire fixing resin portions 11 are filled not only between the second metal wires 8 and the third metal wires 9 but also in a space under the second metal wires 8. The wire fixing resin portions 11 are filled between the third metal wires 9 and the upper surface of the first semiconductor element 4 and are formed inside the first semiconductor element 4 (an inner side of the outline of the element 4).

As the liquid resin which is a material for forming the wire fixing resin portions 11, used is a liquid composition of insulative thermosetting resin such as epoxy resin or silicone resin, for instance. The liquid resin may be a liquid composition of light-curing resin such as an ultra violet-curing type. The thermosetting or light-curing liquid resin is applied from above the third metal wires 9 so as to couple the wires which are adjacent in a plane direction and in a height direction. The liquid resin is filled between the metal wires and further between the metal wires and the semiconductor elements due to its own weight and capillary action. A coating layer (filling layer) of such liquid resin is thermally cured or optically cured, whereby the wire fixing resin portions 11 are formed.

The sealing resin layer 10 is formed after the second and third metal wires 8, 9 are fixed by the wire fixing resin portions 11. Specifically, after the wire fixing resin portions 11 fixing the second and third metal wires 8, 9 are formed by the application and curing of the liquid resin, a stack of the wiring board 2 and the semiconductor elements 4, 6, 7 is set in a mold. A sealing resin material such as epoxy resin is supplied into the mold by, for example, injection molding. The sealing resin material is cured to be formed into the sealing resin layer 10. In this manner, the stacked-type semiconductor device 1 is fabricated.

By forming the sealing resin layer 10 after the long-looped second and third metal wires 8, 9 are fixed above the first semiconductor element 4 by the wire fixing resin portions 11, it is possible to prevent wire sweep which is caused by the resin streams at the time of the molding. This can inhibit the occurrence of a short circuit ascribable to the contact between the wires, enabling improved manufacturing yield and reliability of the semiconductor device 1. Further, since the wire sweep at the time of the molding is prevented, semiconductor elements can be more variably combined for stacking. Since the prevention of the wire sweep need not be considered in the selection of the sealing resin, a resin material selected in view of other specific respects (for example, filling property and warp) can be used, which enables further improvement in the manufacturing yield of the semiconductor device 1.

In the stacked-type semiconductor device 1 shown in FIG. 2, the liquid resin forming the wire fixing resin portions 11 is applied from above the third metal wires 9. At this time, the liquid resin, when applied, does not spread beyond the outline of the first semiconductor element 4 owing to its surface tension. For example, if the liquid resin should spread beyond the outline of the first semiconductor element 4, the wire fixing resin portions 11 formed from the cured liquid resin might appear on the surface of the semiconductor device (semiconductor package) 1. In such a case, the wire fixing resin portions 11 need to satisfy the same flame resistance standard as that of the sealing resin layer 10.

Since the liquid resin forming the wire fixing resin portions 11 is applied without spreading beyond the outline of the first semiconductor element 4, only handlability such as a coating property and a filling property needs to considered in the selection of the liquid resin of the wire fixing resin portions 11. Moreover, low-viscosity liquid resin can be used. The low-viscosity liquid resin, if used, gathers into a space between the first semiconductor element 4 and the third metal wires 9 due to its capillary action, which makes it possible to apply (fill) the liquid resin only in an area under the third metal wires 9. This makes it possible to prevent a poor external appearance and the like which would be caused if the wire fixing resin portions 11 should appear on the surface of the semiconductor device 1 in which the resin thickness above the third metal wires 9 is several tens μm or less (not thicker than about 50 μm).

Further, since the liquid resin gathers into the area under the third metal wires 9 due to its capillary action, the liquid resin only needs to reinforce 1 mm (for example, 1 mm to 3 mm) portions of the metal wires 9 or more if, for example, the long-looped third metal wires 9 are 5 mm long and the longest possible length of the wires whose wire sweep can be prevented in normal resin molding is 4 mm. Accordingly, high application precision (jetting precision) of the liquid resin is not required, which can suppress an increase in manufacturing cost accompanying the formation of the wire fixing resin portions 11.

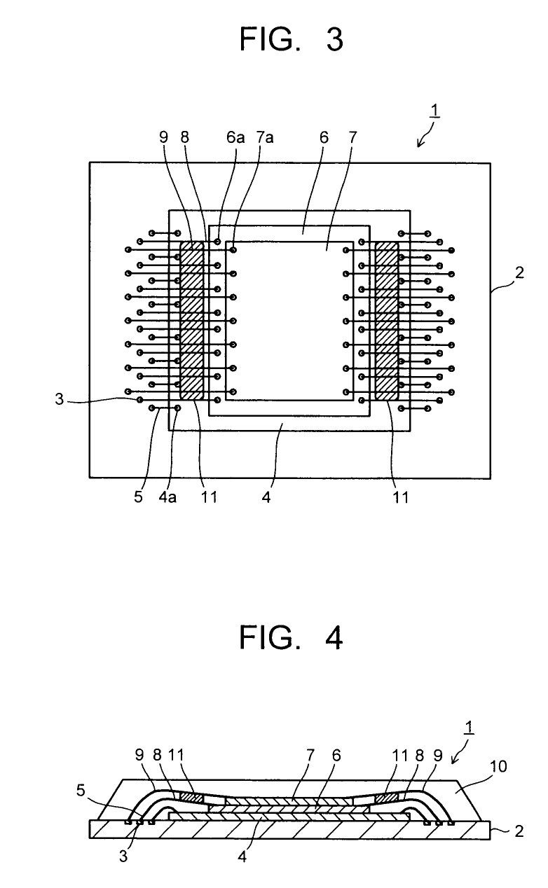

As described above, the wire fixing resin portions 11 only need to be filled at least between the second metal wires 8 and the third metal wires 9. In the stacked-type semiconductor device 1 shown in FIG. 3 and FIG. 4, the wire fixing resin portions 11 are filled only in the space between the second metal wires 8 and the third metal wires 9. By controlling viscosity, an application amount, an application rate, and so on of the liquid resin when the liquid resin is applied to form the wire fixing resin portions 11, it is possible to fill the wire fixing resin portions 11 only in the space between the second metal wires 8 and the third metal wires 9.

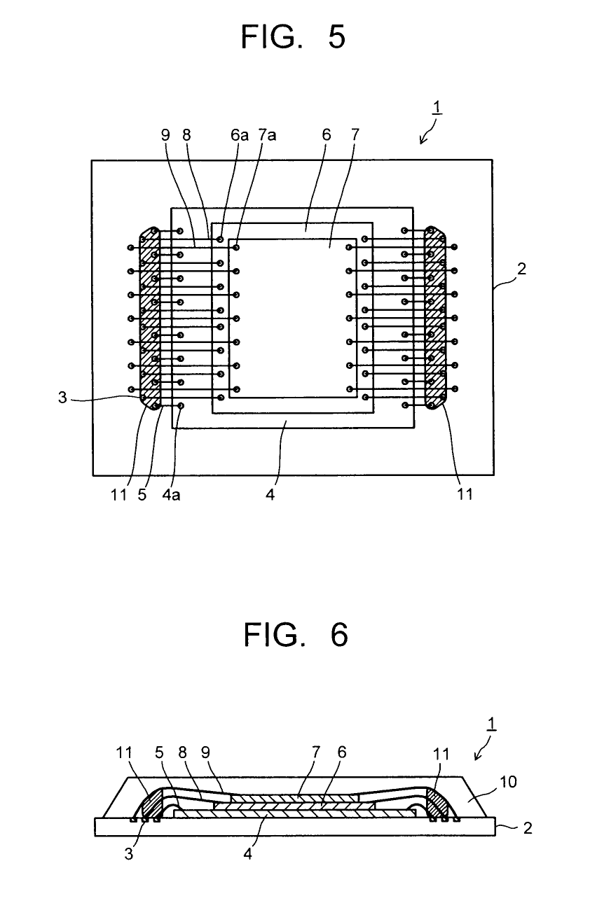

At this time, since the second metal wires 8 and the third metal wires 9 are fixed (coupled) by the wire fixing resin portions 11 while kept a certain distance apart from each other, the occurrence of a short circuit due to the contact between the wires can be inhibited even if the metal wires 8, 9 are displaced due to the resin streams at the time of the molding. By forming the wire fixing resin portions 11 in the space between the second metal wires 8 and the third metal wires 9, it is possible to set the formation positions of the wire fixing resin portions 11 at places other than the area above the first semiconductor element 4. For example, as shown in FIG. 5 and FIG. 6, the wire fixing resin portions 11 can be formed along rising portions of the second and third metal wires 8, 9.

Among the wire sweeps of the bonding wires at the time of the molding of a resin sealing portion of a typical semiconductor package, tilting-down of bending points between their portions rising from a substrate and their flat portions parallel to a horizontal plane poses a problem rather than the displacement of their flat portions. In this view of the above, the wire fixing resin portions 11 are formed along the rising portions of the second and third metal wires 8, 9 to integrally couple them as shown in FIG. 5 and FIG. 6, which can effectively inhibit the bending points from tilting down due to the wire sweep, and as a result can inhibit the occurrence of a short circuit caused by the tilting-down of the wires.

When the wire fixing resin portions 11 are formed along the rising portions of the second and third metal wires 8, 9, a relatively small amount of resin is required for preventing the wire sweep. FIG. 5 and FIG. 6 show a state where the wire fixing resin portions 11 are filled in an area including the space between the second and third metal wires 8, 9 and the space between the first and second metal wires 5, 8. The wire fixing resin portions 11 may be filled in the space between the first metal wires 5 and the third metal wires 9. In this case, since the long-looped metal wires 8, 9 are fixed to the short-looped metal wires 5, the wire sweep of the second and third metal wires 8, 9 can be more effectively inhibited.

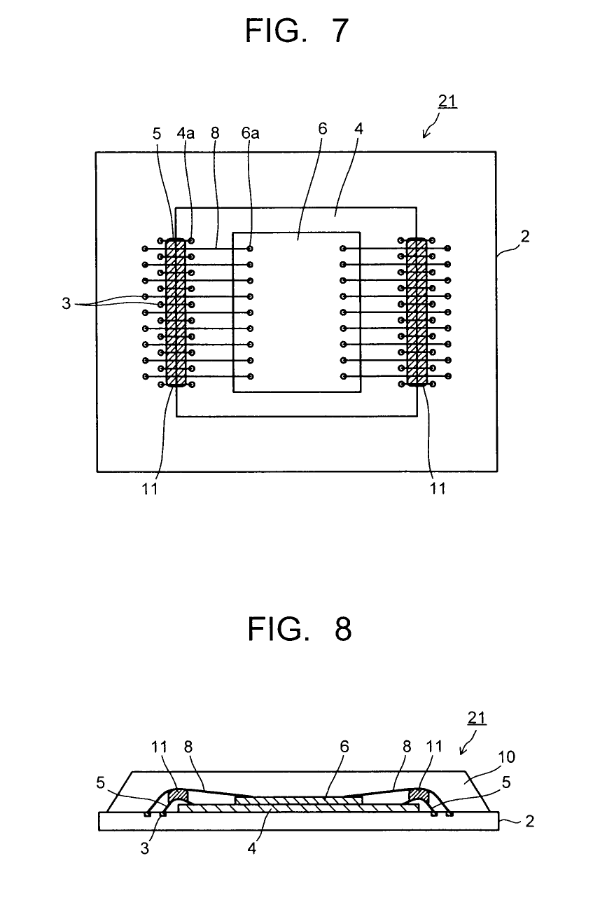

Next, a semiconductor device according to a second embodiment of the present invention will be described with reference to FIG. 7 to FIG. 12. FIG. 7 is a plane view showing the structure of the semiconductor device according to the second embodiment, and FIG. 8 is its cross-sectional view. The same portions as those of the first embodiment will be denoted by the same reference numerals and symbols and description thereof will be partly omitted. In the stacked-type semiconductor device 21 shown in FIG. 7 and FIG. 8, a first semiconductor element 4 and a second semiconductor element 6 are stacked on a wiring board 2. The other structure is the same as that of the semiconductor device 1 of the first embodiment.

The first semiconductor element 4 is bonded on an element mounting surface (upper surface) of the wiring board 2 via an adhesive layer (not shown). The first semiconductor element 4 has first electrode pads 4a arranged in line along two opposed sides among sides forming the outline of the first semiconductor element 4. The first electrode pads 4a are electrically connected to connection pads 3 of the wiring board 2 via first metal wires 5. The first metal wires 5 are wired from the first electrode pads 4a toward the connection pads 3 or from the connection pads 3 toward the first electrode pads 4a.

The second semiconductor element 6 is bonded on the first semiconductor element 4 via an adhesive layer (not shown). The second semiconductor element 6 is stacked on the first semiconductor element 4, its disposition direction being aligned so that its second electrode pads 6a come close to the first electrode pads 4a of the first semiconductor element 4. Specifically, the second electrode pads 6a are arranged in line along two sides positioned near the electrode arranged sides (two opposed sides) of the first semiconductor element 4. The second electrode pads 6a are electrically connected to the connection pads 3 of the wiring board 2 via second metal wires 8. The second metal wires 8 are wired in the same direction as the first metal wires 5. The second semiconductor element 6 is smaller than the first semiconductor element 4. The first and second semiconductor elements 4, 6 are stacked with their electrodes pads 4a, 6a exposed, that is, in a face-up state so that the electrode pads 4a, 6a are disposed in the same layout and in the same arrangement direction.

On the wiring board 2 on which the first and second semiconductor elements 4, 6 are mounted, a sealing resin layer 10 made of, for example, epoxy resin is formed by molding. The first and second semiconductor elements 4, 6, the metal wires 5, 8, and so on are integrally sealed by the sealing resin layer 10. These elements constitute the semiconductor device 21 having a stacked multi-chip package structure.

The semiconductor device 21 of the second embodiment has wire fixing portions 11 fixing the second metal wires 8, the wire fixing portions 11 being formed by curing liquid resin applied on the first and second metal wires 5, 8. The wire fixing resin portions 11 are formed between the first metal wires 5 and the second metal wires 8. In the semiconductor device 21 shown in FIG. 8, the wire fixing resin portions 11 are filled in a space between the first metal wires 4 and the second metal wires 8 to fix the long-looped second metal wires 8 to the short-looped first metal wires 5.

Wire sweep of the long-looped second metal wires 8 due to resin streams at the time of the subsequent molding can be prevented since the second metal wires 8 are thus fixed to the short-looped first metal wires 5 by the wire fixing resin portions 11. This inhibits the occurrence of a short circuit ascribable to the contact between wires, realizing increased manufacturing yield and reliability of the semiconductor device 21. Further, since the wire sweep at the time of the molding is prevented, semiconductor elements can be more variably combined for stacking. Defects of the sealing resin layer 10 can be reduced depending on the selection of sealing resin, which enables further improvement in manufacturing yield of the semiconductor device 21.

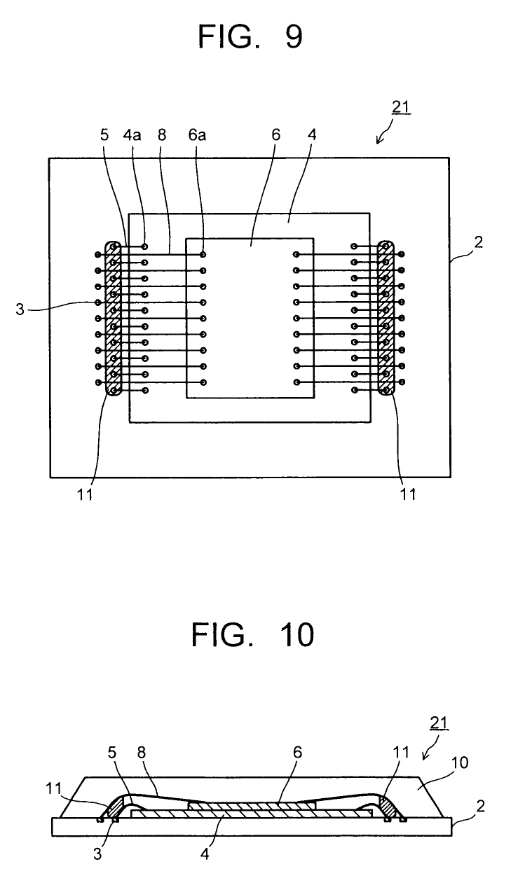

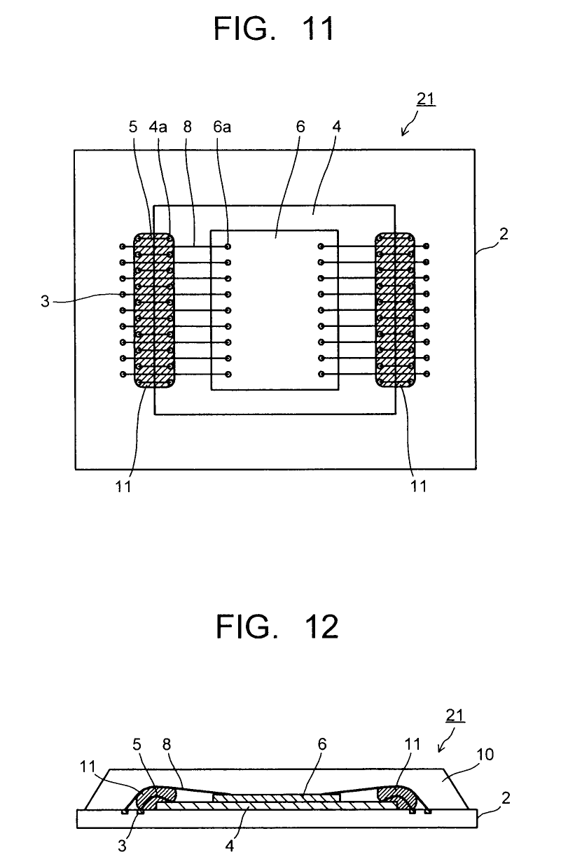

In the semiconductor device 21 of the second embodiment, it is also possible to form the wire fixing resin portions 11 along rising portions of the first and second metal wires 5, 8, as shown in FIG. 9 and FIG. 10. In this case, the rising portions of the second metal wires 8 which easily tilt down at the time of resin molding are fixed integrally with the short-looped first metal wires 5 which do not easily tilt down. This can effectively inhibit bending points of the second metal wires 8 from tilting down due to the wire sweep at the time of the resin molding, and as a result, can inhibit the occurrence of a short circuit which would be caused if the second metal wires 8 should tilt down.

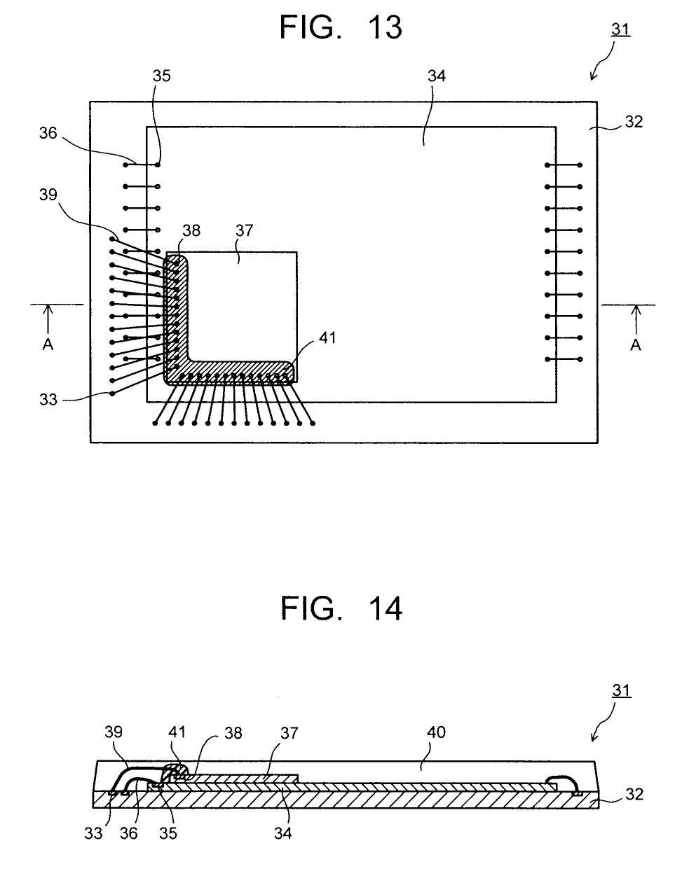

As shown in FIG. 11 and FIG. 12, the wire fixing resin portions 11 may be formed in an area including a space between the first and second metal wires 5, 8 and a space between the first metal wires 5 and the wiring board 2. Such wire fixing resin portions 11 have a function of fixing the second metal wires 8 to the first metal wires 5 and the wiring board 2 and thus can effectively inhibit the wire sweep at the time of the resin molding. However, in this case, the liquid resin forming the wire fixing resin portions 11 drips down and spreads over the wiring board 2 and thus the wiring fixing resin portions 11 formed of the cured liquid resin may possibly appear on a surface of the resin sealing layer 10. Therefore, viscosity, an application amount, and the like of the liquid resin are preferably adjusted so that the liquid resin is filled only in the space under the second metal wires 8.

Next, a semiconductor device according to a third embodiment of the present invention will be described with reference to FIG. 13 to FIG. 17. FIG. 13 is a plane view showing the structure of the stacked-type semiconductor device according to the third embodiment, and FIG. 14 is a cross-sectional view taken along the A-A line in FIG. 13. The semiconductor device 31 shown in FIG. 13 and FIG. 14 has a wiring board 32 as a circuit base for element mounting. The wiring board 32, which has the same structure as that of the wiring board 2 of the first embodiment, includes connection pads 33 which serve as connection portions at the time of wire bonding. External connection terminals such as solder bumps (not shown) are provided on a lower surface side of the wiring board 32. The circuit base may be a lead frame or the like.

A first semiconductor element 34 is bonded on an element mounting surface (upper surface) of the wiring board 32 via an adhesive layer (not shown). The first semiconductor element 34 has first electrode pads 35 which are disposed on the same surface as a surface on which an integrated circuit including transistors is formed. The first electrode pads 35 are electrically connected to the connection pads 33 of the wiring board 32 via first metal wires 36. The first semiconductor element 34 is, for example, a memory element such as a NAND flash memory having a relatively large outside dimension, but is not limited to this.

The first electrode pads 35 are arranged along two opposed sides, concretely, along shorter sides, among sides forming the outline of the first semiconductor element 34. The connection pads 33 of the wiring board 32 are arranged so as to correspond to the respective first electrode pads 35 which are arranged in two rows. The first metal wires 36 are wired from the first electrode pads 35 toward the connection pads 33 or from the connection pads 33 toward the first electrode pads 35. One-side end portions of the first metal wires 36 are connected to the connection pads 33 and the other end portions are connected to the first electrode pads 3.

A second semiconductor element 37 smaller than the first semiconductor element 34 is stacked on the first semiconductor element 34. The second semiconductor element 37 is bonded on the first semiconductor element 34 via an adhesive layer (not shown). The second semiconductor element 37 has second electrode pads 38 disposed on the same surface as a surface on which an integrated circuit including transistors is formed. The second electrode pads 38 are arranged along two adjacent sides among sides forming the outline of the semiconductor element 37. The second semiconductor element 37 has an L-arranged pad structure.

When a semiconductor memory element such as a NAND flash memory is used as the first semiconductor element 34, a possible concrete example of the second semiconductor element 37 is a controller element smaller in outside dimension than the semiconductor memory element. The second semiconductor element 37 is not limited to this and may be a PSRAM (Pseudo Static RAM) or the like which is smaller than the NAND flash memory or the like, similarly to the controller element. The number of the first semiconductor elements 34 is not limited to one and the plural first semiconductor elements 34 may be stacked.

The electrode pads 38 of the second semiconductor element 37 are electrically connected to the connection pads 33 of the wiring board 32 via second metal wires 39. Some of the connection pads 33 of the wiring board 32 are arranged so as to correspond to the second electrode pads 38. The second metal wires 39 are wired from the second electrode pads 38 toward the connection pads 33 or from the connection pads 33 toward the second electrode pads 38. One-side end portions of the second metal wires 39 are connected to the connection pads 33 and the other end portions are connected to the second electrode pads 38.

On the wiring board 32 on which the first and second semiconductor elements 34, 37 are mounted, a sealing resin layer 40 made of, for example, epoxy resin is formed by molding. The first and second semiconductor elements 34, 37, the metal wires 36, 39, and so on are integrally sealed by the sealing resin layer 40. In FIG. 13, the illustration of the sealing resin layer 40 is omitted. Though FIG. 13 and FIG. 14 show the structure in which the two semiconductor elements are stacked, but the number of the stacked semiconductor elements is not limited to this. The number of the stacked semiconductor elements may be three or more.

It is necessary to make the loop height of the second metal wires 39 low on their end portions connected to the second semiconductor elements 37 (element-side end portions) by making rising portions of the second metal wires 39 short, in order to reduce the thickness of the sealing resin layer 40 and accordingly reduce the thickness of the semiconductor device 31. Consequently, a gap between the second semiconductor element 37 and the element-side end portions of the second metal wires 39 becomes narrow, which may cause the leakage between the second semiconductor element 37 and the second metal wires 39. Therefore, the semiconductor device 31 of the third embodiment includes an insulating resin portion 41 having a cured matter of liquid resin to cover the element-side end portions of the second metal wires 39.

Specifically, the liquid resin is applied on the element-side end portions of the second metal wires 39 and a coating layer of this liquid resin is cured to be formed into the insulating resin portion 41 so as to surely insulate the second semiconductor element 37 and the second metal wires 39 from each other. As the liquid resin which is a material for forming the insulating resin portion 41, used is a liquid composition of insulative thermosetting resin such as epoxy resin or silicone resin, for instance. The liquid resin may be a liquid composition of light-curing resin such as an ultra violet-curing type. The thermosetting or light-curing liquid resin composition is applied on the element-side end portions of the metal wires 39 disposed along the electrode arranged sides of the second semiconductor element 37, and a coating layer of this liquid resin composition is thermally cured or optically cured, whereby the insulating resin portion 41 is formed.

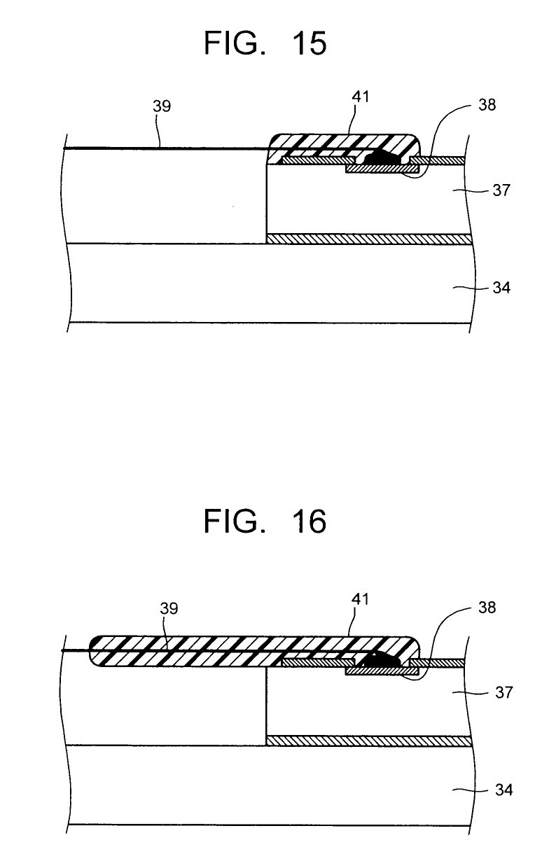

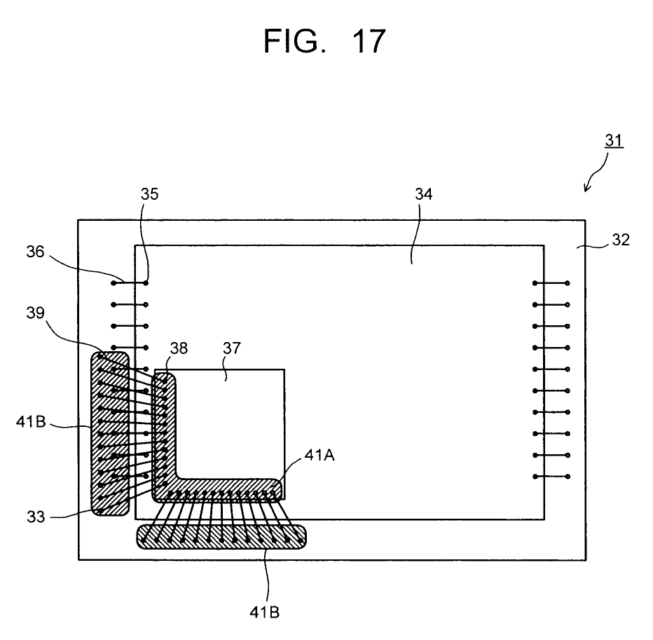

Forming the insulating resin portion 41 made of the cured matter of the liquid resin on the element-side end portions of the second metal wires 39 can more surly insulate the second semiconductor element 37 and the second metal wires 39 from each other. Therefore, it is possible to prevent the leakage between the second semiconductor element 37 and the second metal wires 39 even if the second metal wires 39 whose loop height is low are wired above the second semiconductor element 37. It is only necessary that the insulating resin portion 41 be formed to cover at least the element-side end portions of the second metal wires 39 as shown in FIG. 15. The insulating resin portion 41 may be formed to extend along the second metal wires 39 as shown in FIG. 16. In this case, the insulating resin portion 41 may reach an area above the first semiconductor element 34.

It is possible to more surely insulate the second metal wires 39 from one another by forming the insulating resin portion 41 so as to cover not only the element-side end portions of the second metal wires 39 but also their portions wired toward the connection pads 33. As a result, the leakage between the adjacent metal wires 39 can be inhibited. This is effective when a large number of wires are provided and thus are arranged at narrow pitches. If the wires are arranged at narrow pitches, the liquid resin, when supplied onto the second metal wires 39, is applied in a layered form while covering the peripheries of the second metal wires 39 due to the surface tension. The coating layer of such liquid resin is cured, whereby the insulating resin portion 41 effective for the inhibition of the leakage between the wires is obtained.

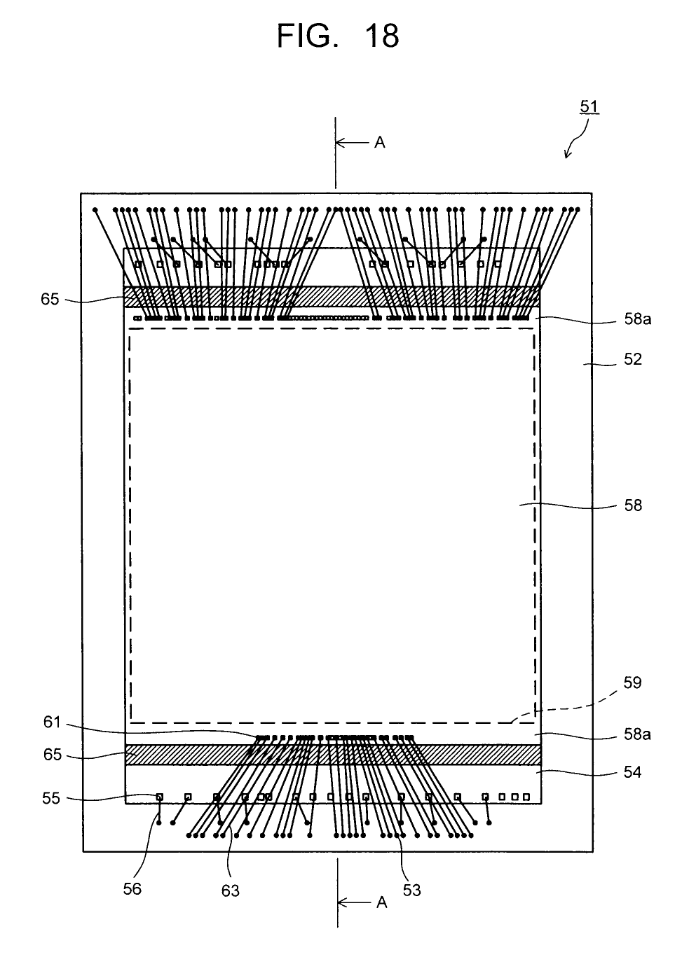

The formation position of the insulating resin portion 41 is not limited to the element-side end portions of the second metal wires 39. That is, it is also effective to adopt an insulating resin portion 41B covering end portions connected to the connection pads 33 (board-side end portions) of the second metal wires 39, in addition to an insulating resin portion 41A formed on the element-side end portions of the second metal wires 39, as shown in FIG. 17. In addition to these, an insulating resin portion covering middle portions of the second metal wires 39 may be added. The insulating resin portion 41B provided on the board-side end portions of the second metal wires 39 also has an effect of preventing the wire sweep, the tilting down of the wires, and the like at the time of resin molding.

The semiconductor device 31 according to the third embodiment can be combined with any of the semiconductor devices 1, 21 according to the first and second embodiments. Specifically, the insulating resin portion 41 preventing the leakage between the metal wires and between the metal wires and the semiconductor element can be employed in combination with the wire fixing resin portion 11 fixing the metal wires. In some case, the insulating resin portion 41 can be provided with the function of the wire fixing resin portion 11. The liquid resin applied and cured on the metal wires can provide various effects such as the prevention of the wire sweep, the prevention of the leakage between the metal wires and the semiconductor element, and the prevention of the leakage and short circuit between the metal wires.

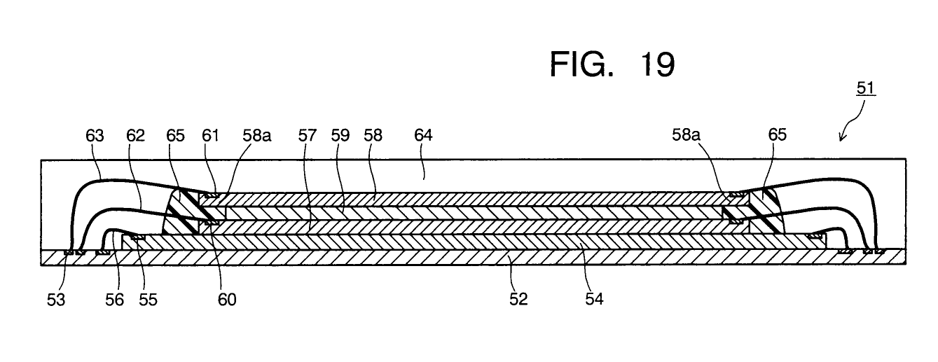

Next, a semiconductor device according to a fourth embodiment of the present invention will be described with reference to FIG. 18 and FIG. 19. FIG. 18 is a plane view showing the structure of the semiconductor device according to the fourth embodiment, and FIG. 19 is a cross-sectional view taken along the A-A line in FIG. 18. The stacked-type semiconductor device 51 shown in FIG. 18 and FIG. 19 has a wiring board 52 as a circuit base for element mounting. The wiring board 52, which has the same structure as that of the wiring board 2 of the first embodiment, includes connection pads 53 which serve as connection portions at the time of wire bonding. External connection terminals such as solder bumps (not shown) are provided on a lower surface side of the wiring board 52. The circuit base may be a lead frame or the like.

A first semiconductor element 54 is bonded on an element mounting surface (upper surface) of the wiring bond 52 via an adhesive layer (not shown). The first semiconductor element 54 has first electrode pads 55 which are disposed on the same surface as a surface on which an integrated circuit including transistors is formed. The first electrode pads 55 are electrically connected to the connection pads 53 of the wiring board 52 via first metal wires 56. The first semiconductor element 54 is, for example, a memory element such as a NAND flash memory having a relatively large outside dimension, but is not limited to this.

The first electrode pads 55 are arranged along two opposed sides, concretely, along shorter sides, among sides forming the outline of the first semiconductor element 54. The connection pads 53 of the wiring board 52 are arranged so as to correspond to the respective first electrode pads 55 which are arranged in two rows. The first metal wires 56 are wired from the first electrode pads 55 toward the connection pads 53 or from the connection pads 53 toward the first electrode pads 55. One-side end portions of the first metal wires 56 are connected to the connection pads 53 and the other end portions are connected to the first electrode pads 55.

On the first semiconductor element 54, a second semiconductor element 57 and a third semiconductor element 58 are stacked with a spacer layer 59 there between. The second semiconductor element 57, the spacer layer 59, and the third semiconductor element 58 are bonded via adhesive layers (not shown). The second and third semiconductor elements 57, 58 have second and third electrode pads 60, 61 disposed on the same surfaces as surfaces on each of which an integrated circuit including transistors is formed. The second semiconductor element 57 and the third semiconductor element 58 have the same rectangular shape, and there between, the spacer layer 59 smaller in outside dimension than the second and third semiconductor elements 57, 58 are disposed.

Since the spacer layer 59 whose longer-side length is shorter than that of the second semiconductor elements 57 and the third semiconductor elements 58 is interposed between the second semiconductor element 57 and the third semiconductor element 58, portions 58a, of an outer peripheral portion of the third semiconductor element 58, including the sides along which the electrode pads 61 are arranged (electrode arranged sides (both shorter sides)) protrude in a visor shape. That is, the both shorter sides of the third semiconductor element 58 have an overhanging structure, and spaces (hollow portions) are formed between the visor-shaped protruding portions 58a and the second semiconductor element 57. The second electrode pads 60 are exposed to the hollow portions which are formed between the second semiconductor element 57 and the third semiconductor element 58 due to the spacer layer 59.

The second and third semiconductor elements 57, 58 are stacked on the first semiconductor element 54, being aligned so that the second and third electrode pads 60, 61 come close to the electrode pads 55 of the first semiconductor element 54. That is, the second and third electrode pads 60, 61 are disposed along two sides (both shorter sides) positioned near the electrode arranged sides (opposed two sides) of the first semiconductor element 54. As the second and third semiconductor elements 57, 58, memory elements (DRAM or the like) having a relatively large outside dimension but smaller than the first semiconductor element 54 are employed, but this is not restrictive.

The second and third electrode pads 60, 61 are electrically connected to the connection pads 53 of the wiring board 52 via second and third metal wires 62, 63, similarly to the first electrode pads 55. The second and third metal wires 62, 63 are wired in the same direction as the first metal wires 56, and one-side end portions thereof are connected to the connection pads 53 and the other end portions are connected to the second and third electrode pads 60, 61. The metal wires (bonding wires) 56, 62, 63 connected to the respective electrode pads 55, 60, 61 are wired in the same direction.

On the wiring board 52 on which the semiconductor elements 54, 57, 58 are mounted, a sealing resin layer 64 made of, for example, epoxy resin is formed by molding. The first, second, and third semiconductor elements 54, 57, 58, and the metal wires 56, 62, 63 are integrally sealed by the sealing resin layer 64. In FIG. 18, the illustration of the sealing resin layer 64 is omitted. Though FIG. 18 and FIG. 19 show the structure in which the three semiconductor elements are stacked, but the number of the stacked semiconductor elements is not limited to this. The number of the stacked semiconductor elements may be two or may be four or more.

As described above, the outer peripheral portion of the third semiconductor element 58 partly protrudes in the visor shape, and accordingly, under the visor-shaped protruding portions 58a, the hollow portions exist between the second semiconductor element 57 and the hollow portions 58a. The metal wires 63 existing in front of the hollow portions make it difficult to fill the hollow portions with a resin material which is a material for forming the sealing resin layer 64. In particular, if a semiconductor element having a large number of terminals such as a DRAM is employed as the third semiconductor element 58, an area under the metal wires 63 is like the inside of a spider-web-like tunnel, resulting in further lower filling property of the sealing resin material. Portions left unfilled with the sealing resin (voids) will be a cause of a defect such as a crack of the semiconductor device 51 since air in these portions expands in a high-temperature atmosphere.

Therefore, in the fourth embodiment, filling resin portions 65 made of a cured matter of liquid resin are disposed in the hollow portions between the visor-shaped protruding portions 58a of the third semiconductor element 58 and the second semiconductor element 57. Specifically, the liquid resin is filled to the hollow portions between the visor-shaped protruding portions 58a and the second semiconductor element 57, and this liquid resin is cured, whereby the filling resin portions 65 are formed. The filling resin portions 65 have cured matter of the liquid resin. By filling up the hollow portions between the visor-shaped protruding portions 58a and the second semiconductor element 57 with the filling resin portions 65 in advance, it is possible to inhibit the generation of voids ascribable to the unfilling of the sealing resin layer 64 and further to inhibit the occurrence of a crack ascribable to the expansion of air in the voids. It is possible to provide the semiconductor device 51 excellent in manufacturing yield and reliability.

As the liquid resin forming the filling resin portions 65, usable is a liquid composition of insulative thermosetting resin such as, for example, epoxy resin or silicone resin. The liquid resin may be a liquid composition of light-curing resin such as an ultra violet-curing type. The thermosetting or light-curing liquid resin composition is supplied from above the third metal wires 63 and is filled in the hollow portions between the visor-shaped protruding portions 58a of the third semiconductor element 58 and the second semiconductor element 57 via the gaps between the metal wires 63. An underfill technique is applicable for filling the liquid resin. Then, the filled liquid resin is thermally cured or optically cured, whereby the filling resin portions 65 are formed.

By molding the sealing resin material to form the sealing resin layer 64 after the hollow portions between the visor-shaped protruding portions 58a of the third semiconductor element 58 and the second semiconductor element 57 are filled up with the filling resin portions 65, it is possible to prevent some portions from being left unfilled with the sealing resin. This can inhibit the generation of voids ascribable to a filling failure of the sealing resin, and as a result, inhibit the occurrence of a crack in the sealing resin layer 64, which can improve manufacturing yield and reliability of the stacked-type semiconductor device 51. Further, semiconductor elements can be more variably combined for stacking since the voids at the time of resin sealing is prevented. Since the inhibition of the voids need not be considered in the selection of the sealing resin, a resin material selected in view of other specific respects (for example, wire sweep) can be used, which enables improvement in the manufacturing yield of the semiconductor device 51.

The semiconductor device 51 according to the fourth embodiment can be combined with any of the semiconductor devices 1, 21, 31 according to the first, second, and third embodiments. Specifically, the filling resin portions 65 filling the hollow portions existing under the visor-shaped protruding portions 58a can be employed in combination with any of the wire fixing rein portion 11 fixing the metal wires, the insulating resin portion 41 preventing the leakage between the metal wires and between the metal wires and the semiconductor element. Further, in some case, the filling resin portions 65 can be provided with the functions of the wire fixing resin portion 11 and the insulating resin portions 41. The adoption of the application and curing of the liquid resin can provide various effects such as the prevention of the wire sweep, the prevention of the leakage between the metal wires and the semiconductor element, the prevention of the leakage and short circuit between the metal wires, and the inhibition of voids in the sealing resin layer.

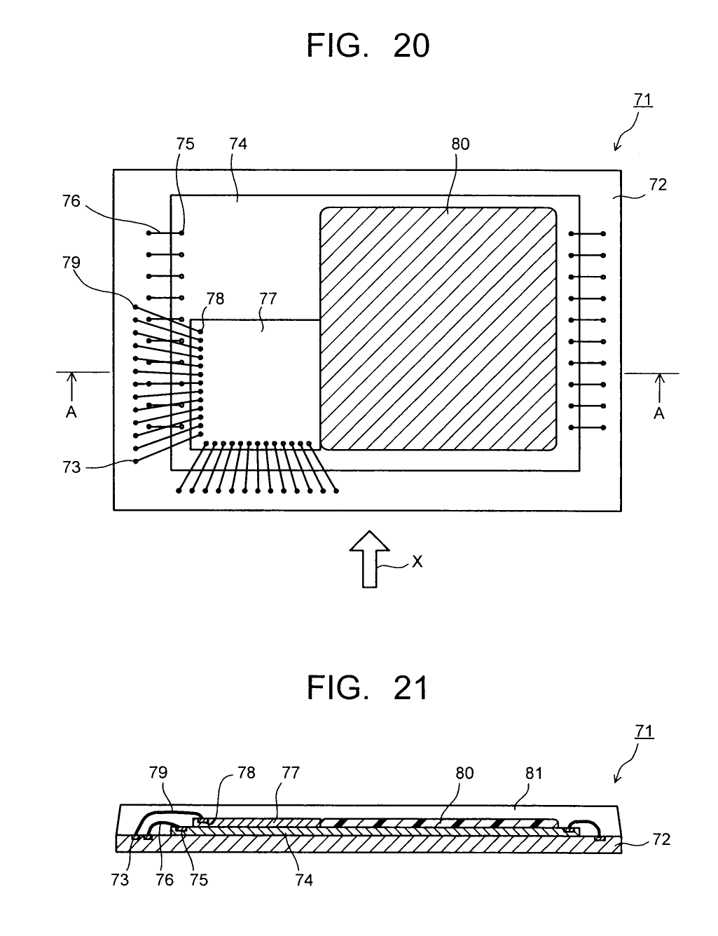

Next, a semiconductor device according to a fifth embodiment of the present invention will be described with reference to FIG. 20 to FIG. 25. FIG. 20 is a plane view showing the structure of the stacked-type semiconductor device according to the fifth embodiment, and FIG. 21 is a cross-sectional view taken along the A-A line in FIG. 20. The semiconductor device 71 shown in FIG. 20 and FIG. 21 has a wiring board 72 as a circuit base for element mounting. The wiring board 72, which has the same structure as that of the wiring board 2 of the first embodiment, includes connection pads 73 which serve as connection portions at the time of wire bonding. External connection terminals such as solder bumps (not shown) are provided on a lower surface side of the wiring board 72. The circuit base may be a lead frame or the like.

A first semiconductor element 74 is bonded on an element mounting surface (upper surface) of the wiring bond 72 via an adhesive layer (not shown). The first semiconductor element 74 has first electrode pads 75 which are disposed on the same surface as a surface on which an integrated circuit including transistors is formed. The first electrode pads 75 are electrically connected to the connection pads 73 of the wiring board 72 via first metal wires 76. The first semiconductor element 74 is, for example, a semiconductor memory element such as a NAND flash memory having a relatively large outside dimension, but is not limited to this.

The first electrode pads 75 are arranged along two opposed sides, concretely, along shorter sides, among sides forming the outline of the first semiconductor element 74. The connection pads 73 of the wiring board 72 are arranged so as to correspond to the respective first electrode pads 75 which are arranged in two rows. The first metal wires 76 are wired from the first electrode pads 75 toward the connection pads 73 or from the connection pads 73 toward the first electrode pads 75. One-side end portions of the first metal wires 76 are connected to the connection pads 73 and the other end portions are connected to the first electrode pads 75.

A second semiconductor element 77 smaller than the first semiconductor element 74 is stacked on the first semiconductor element 74. The second semiconductor element 77 is bonded on the first semiconductor element 74 via an adhesive layer (not shown). The second semiconductor element 77 has second electrode pads 78 disposed on the same surface as a surface on which an integrated circuit including transistors is formed. The second electrode pads 78 are arranged along adjacent two sides among sides forming the outline of the second semiconductor element 77. The second semiconductor element 77 has an L-arranged pad structure.

In the structure in which a memory element such as a NAND flash memory is used as the first semiconductor element 74, a possible concrete example of the second semiconductor element 77 is a controller element smaller in outside dimension than the memory element. The second semiconductor element 77 is not limited to this and may be a PSRAM (Pseudo Static RAM) or the like which is smaller than the NAND flash memory or the like similarly to the controller element. The number of the first semiconductor elements 74 is not limited to one, and the plural first semiconductor elements 74 may be stacked.

The electrode pads 78 of the second semiconductor element 77 are electrically connected to the connection pads 73 of the wiring board 72 via second metal wires 79. Some of the connection pads 73 of the wiring board 72 are arranged so as to correspond to the second electrode pads 78. The second metal wires 79 are wired from the second electrode pads 78 toward the connection pads 73 or from the connection pads 73 toward the second electrode pads 78. One-side end portions of the second metal wires 79 are connected to the connection pads 73 and the other end portions are connected to the second electrode pads 78.

On the first semiconductor element 74, a buried resin portion 80 is formed on a surface region excluding a region on which the second semiconductor element 77 is stacked. The buried resin portion 80 is formed on the surface region of the first semiconductor element 74 to eliminate difference in level on the first semiconductor element 74 based on the second semiconductor element 77. As liquid resin forming the buried resin portion 80, usable is a liquid composition of insulative thermosetting resin such as, for example, epoxy resin or silicone resin. The liquid resin may be a liquid composition of light-curing resin such as an ultra violet-curing type. The thermosetting or light-curing liquid resin composition is applied on the first semiconductor element 74 and a coating layer of this liquid resin composition is thermally cured or optically cured, whereby the buried resin portion 80 is formed. The buried resin portion 80 has a cured matter of the liquid resin.

On the wiring board 72 on which the first and second semiconductor elements 74, 77 are mounted, a sealing resin layer 81 made of, for example, epoxy resin is formed by molding. The first and second semiconductor elements 74, 77, the metal wires 76, 79, the buried resin portion 80, and so on are integrally sealed by the sealing resin layer 81. In FIG. 20, the illustration of the sealing resin layer 81 is omitted. Though FIG. 20 and FIG. 21 show the structure in which the two semiconductor elements are stacked, but the number of the stacked semiconductor elements is not limited to this. The number of the stacked semiconductor elements may be three or more.

As described above, as a result of stacking the second semiconductor element 77 smaller than the first semiconductor element 74 on the first semiconductor element 74, a large level difference is formed on the first semiconductor element 74 due to the second semiconductor element 77. The level difference due to the second semiconductor element 77 causes a difference in filling time of streams of the resin (shown by the arrow X in FIG. 20) when the sealing resin layer 81 is formed by molding (transferring or the like). Therefore, the resin streams easily let air in on a downstream side (downstream side in terms of the resin streams) of the second semiconductor element 77, into which the resin streams flow around. This may cause the generation of voids (internal cavities). Therefore, in the fifth embodiment, the buried resin portion 80 is formed on the surface region of the first semiconductor element 74 excluding the region on which the second semiconductor element 77 is stacked.

FIG. 20 shows a state where the buried resin portion 80 is formed on the first semiconductor element 74 in line with the second semiconductor element 77 so as to be buried in a stepped-down region formed due to the second semiconductor element 77. In this case, the buried resin portion 80 fills about ¾ of the level difference region on the surface of the first semiconductor element 74 (the surface region excluding the region on which the second semiconductor element 77 is stacked). The level difference region on the first semiconductor element 74 is thus made smaller by the buried resin portion 80 filing at least part of the level difference region, which allows streams of the resin flowing outside the first semiconductor element 74 to join together. This can inhibit the generation of voids (inner cavities) which might occur if the resin streams should let air in. The semiconductor element 74 is favorably protected from a marking laser beam and the like.

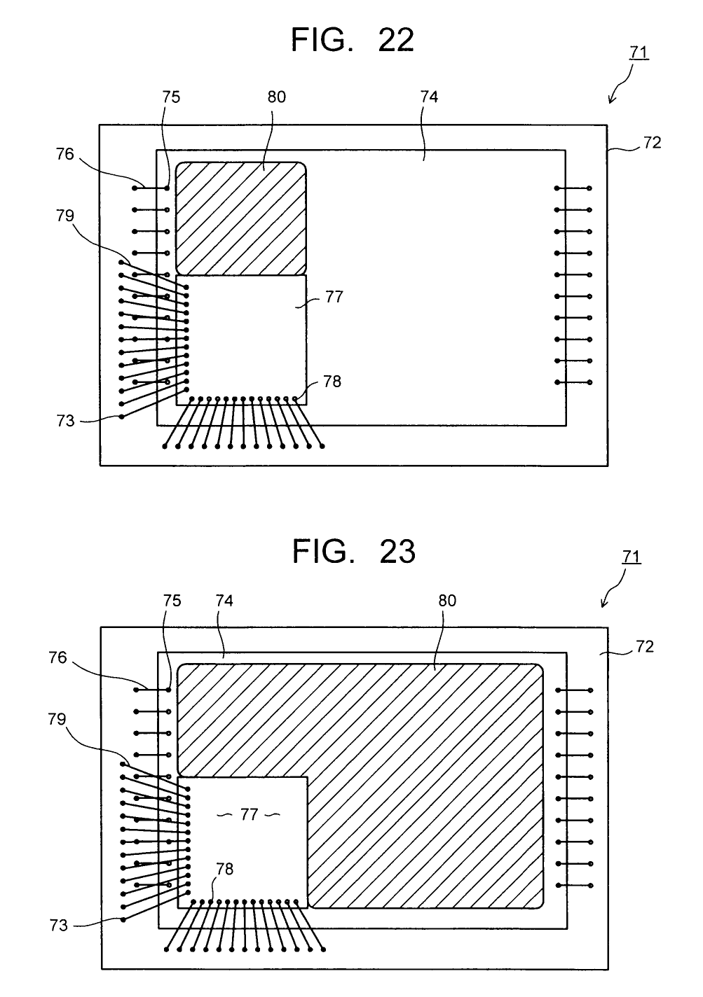

The buried resin portion 80 may be formed on a stepped-down region on the first semiconductor element 74 where the resin streams easily let air in, that is, on the stepped-down region corresponding to a downstream side of the second semiconductor element 77, as shown in FIG. 22. This structure can inhibit the generation of voids (cavities) in the sealing resin layer 81 since air, even if let into the resin streams, is pushed out of the semiconductor device 71. Alternatively, the buried resin portion 80 may be formed on the entire surface of the stepped-down region on the first semiconductor element 74, as shown in FIG. 23. This structure can more effectively protect the semiconductor element 74 since the buried resin portion 80 itself functions as a protective layer against the laser beam and the like.

The sealing resin layer 81 is formed by molding (transferring or the like) of the sealing resin material after at least part of the level difference region formed on the first semiconductor element due to the second semiconductor element 77 (the surface region excluding the region on which the second semiconductor element 77 is stacked) is thus filled with the buried resin portion 80, and consequently, it is possible to inhibit the generation of voids which might occur if the resin streams should let air in. Accordingly, the semiconductor element 74 is favorably protected, which enables improved manufacturing yield and reliability of the stacked-type semiconductor device 71. Further, since the inhibition of the voids need not be considered in the selection of the sealing resin, resin which is selected in view of other specific respects (for example, wire sweep) can be used, which enables further improvement in the manufacturing yield of the semiconductor device 51.

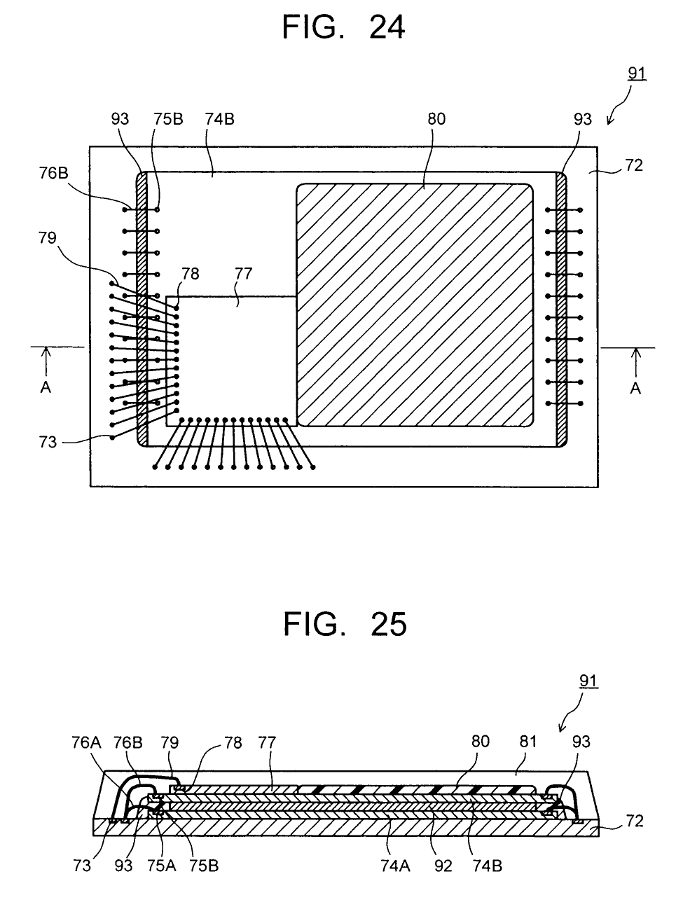

The structure for inhibiting the generation of the voids by the buried resin portion 80 of the fifth embodiment can more effectively improve resin sealability if used in combination with the device structure according to the fourth embodiment. FIG. 24 and FIG. 25 show a stacked-type semiconductor device 91 in which the fourth embodiment and the fifth embodiment are combined. The same portions as those of the fifth embodiment are denoted by the same reference numerals and symbols. In the semiconductor device 91 shown in FIG. 24 and FIG. 25, two semiconductor elements 74A, 74B as the first semiconductor elements 74 are stacked on a wiring board 72 with a spacer layer 92 there between.

The two semiconductor elements 74A, 74B have electrode pads 75A, 75B respectively. Between the semiconductor element 74A and the semiconductor element 74B, the spacer layer 92 whose longer-side length is shorter than that of the semiconductor elements 74A, 74B is interposed, and therefore, outer peripheral portions of the semiconductor element 74B partly protrude in a visor shape. Spaces (hollow portions) are formed between the visor-shaped protruding portions and the semiconductor element 74A, and the electrode pads 75A are exposed to the hollow portions. The electrode pads 75A, 75B of the two semiconductor elements 74A, 74B are electrically connected to connection pads 73 of a wiring board 72 via metal wires 76A, 76B respectively.

In the hollow portions between the visor-shaped protruding portions of the semiconductor element 74B and the semiconductor element 74A, filling resin portions 93 made of a cured matter of liquid resin are formed. On the semiconductor element 74B, a buried resin portion 80 made of a cured matter of liquid resin is further formed on a surface region excluding a region on which the semiconductor element 77B is stacked. By thus employing both of the buried resin portion 80 and the filling resin portions 93, it is possible to inhibit filling failures of sealing resin ascribable to the hollow portions formed due to the visor-shaped protruding portions and ascribable to the level difference formed due to the small semiconductor element. Accordingly, soundness of the sealing resin layer 81 is improved, which enables further improvement in manufacturing yield and reliability of the semiconductor device 91.

The semiconductor device 71 according to the fifth embodiment may be combined with any of the semiconductor devices 1, 21, 31 according to the first, second, and third embodiments. That is, the buried resin portion 80 can be employed in combination with any of the wire fixing resin portion 11 fixing the metal wires, the insulating resin portion 41 preventing the leakage between the metal wires and between the metal wires and the semiconductor element, and so on. Adopting the application and curing of the liquid resin can provide various effects such as the prevention of the wire sweep, the prevention of the leakage between the metal wires and the semiconductor element, the prevention of the leakage and short circuit between the metal wires, the inhibition of voids in the sealing resin layer, and the like.

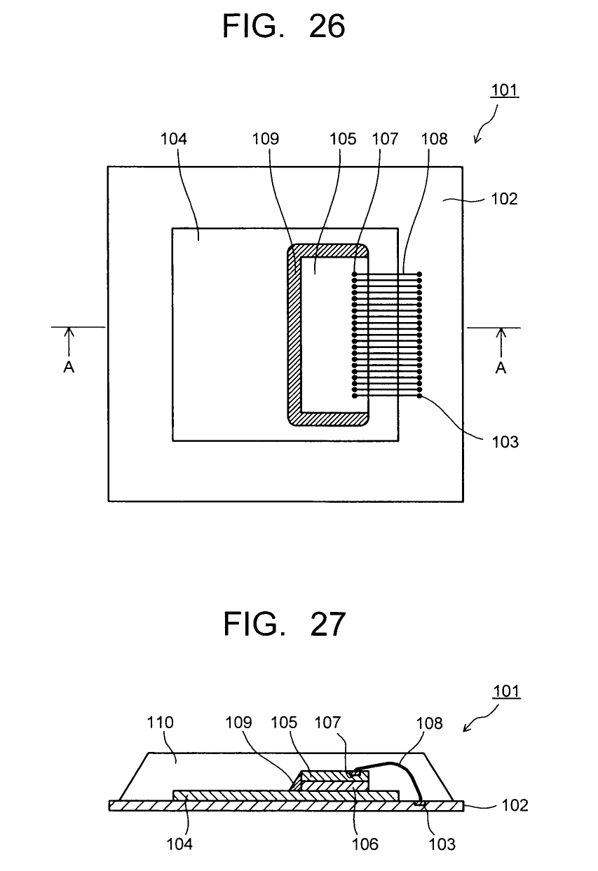

Next, a semiconductor device according to a sixth embodiment of the present invention will be described with reference to FIG. 26 to FIG. 31. FIG. 26 is a plane view showing the structure of a stacked-type semiconductor device according to the sixth embodiment, and FIG. 27 is a cross-sectional view taken along the A-A line in FIG. 26. The semiconductor device 101 shown in FIG. 26 and FIG. 27 has a wiring board 102 as a circuit base for element mounting. The wiring board 102, which has the same structure as that of the wiring board 2 of the first embodiment, includes connection pads 103 which serve as connection portions at the time of wire bonding. External connection terminals (not shown) are provided on a lower surface side of the wiring board 102. The circuit base may be a lead frame or the like.

A first semiconductor element 104 is bonded on an element mounting surface (upper surface) of the wiring board 102 via an adhesive layer (not shown). The first semiconductor element 104 has electrode pads (not shown) which are disposed along at least its one outer side, and these electrode pads are electrically connected to the connection pads of the wiring board 102 via metal wires (not shown). The first semiconductor element 104 is, for example, a memory element such as a NAND flash memory or a DRAM having a relatively large outside dimension, but is not limited to this.

A second semiconductor element 105 smaller than the first semiconductor element 104 is stacked on the first semiconductor element 104. The second semiconductor element 105 is bonded on the first semiconductor element 104 via an adhesive layer 106. As the adhesive layer 106, an adhesive film is generally used. The second semiconductor element 105 has electrode pads 107. The electrode pads 107 are disposed along one outer side of the second semiconductor element 105. The second semiconductor element 105 has a structure in which the pads are disposed on one longer side. The electrode pads 107 of the second semiconductor element 105 are electrically connected to the connection pads 103 of the wiring board 102 via metal wires 108.

When a memory element such as a NAND flash memory is used as the first semiconductor element 104, a possible concrete example of the second semiconductor element 105 is a controller element smaller in outside dimension than the memory element 104. The second semiconductor element 105 is not limited to this and may be a PSRAM (Pseudo Static RAM), a logic element, or the like smaller than the NAND flash memory or the like, similarly to the controller element. The number of the first semiconductor elements 104 is not limited to one and the plural first semiconductor elements 104 may be stacked.

The second semiconductor element 105 is fixed by an element fixing resin portion 109 which is formed along at least one outer peripheral surface including one of outer sides excluding the electrode arranged side of the second semiconductor element 105. Specifically, liquid resin is applied along the outer peripheral surface (outer peripheral portion), of the semiconductor element 105, not including its electrode arranged side and this liquid resin is cured, whereby the element fixing resin portion 109 is formed so as to reduce the vibration of the semiconductor element 105 itself at the time of wire bonding and as a result, to inhibit a decrease of bonding strength of the metal wires 108 ascribable to the vibration of the semiconductor element 105 itself. FIG. 26 and FIG. 27 show a state where the element fixing resin portion 109 is formed along the outer peripheral surfaces (three surfaces) of the semiconductor element 105 not including its electrode arranged side.

As the liquid resin which is a material for forming the element fixing resin portion 109, usable is a liquid composition of insulative thermosetting resin such as, for example, epoxy resin or silicone resin. The liquid resin may be a liquid composition of light-curing resin such as an ultra violet-curing type. The thermosetting or light-curing liquid resin composition is applied on the outer peripheral surfaces (excluding the outer peripheral surface including the electrode arranged side) of the semiconductor element 105, and a coating layer of the liquid resin composition is thermally cured or optically cured, whereby the element fixing resin portion 109 is formed. By forming the element fixing resin portion 109 on the outer peripheral surfaces excluding the outer peripheral surface including the electrode arranged side, it is possible to prevent the pads from being contaminated when the liquid resin is applied.

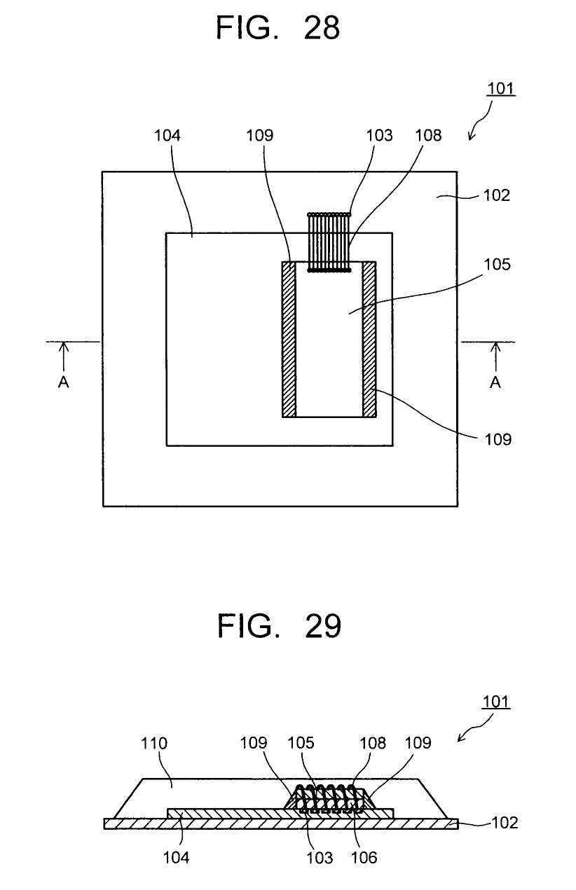

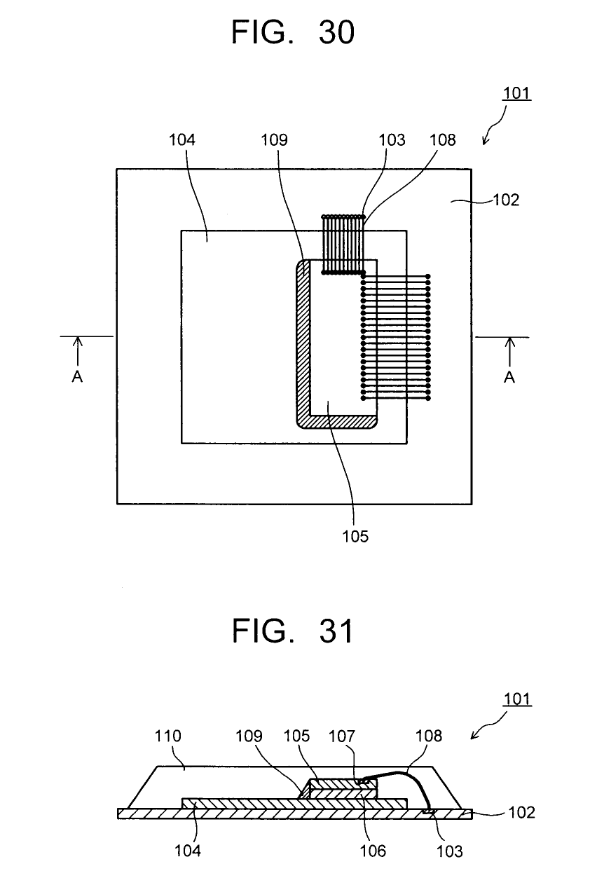

The formation position of the element fixing resin portion 109 can be appropriately set according to the electrode arranged side of the semiconductor element 105. FIG. 28 and FIG. 29 show a second semiconductor element 105 having a structure where the pads are disposed on both shorter sides, as an example. In such a case, the element fixing resin portions 109 are formed along outer peripheral surfaces including both longer sides of the second semiconductor element 105. FIG. 30 and FIG. 31 show a second semiconductor element 105 having an L-arranged pad structure. In such a case, the element fixing resin portion 109 is formed along outer peripheral surfaces including a longer side and a shorter side, of the second semiconductor element 105, which are opposed to its electrode arranged sides. In any case, the element fixing resin portion 109 is formed along a portion not including the electrode arranged side.

On the wiring board 102 on which the first and second semiconductor elements 104, 105 are mounted, a sealing resin layer 110 made of, for example, epoxy resin is formed by molding. The first and second semiconductor elements 104, 105, the metal wires 108, and so on are integrally sealed by the sealing resin layer 110. In FIG. 26, FIG. 28, and FIG. 30, the illustration of the sealing resin layer 110 is omitted. The number of the stacked semiconductor elements is not limited to two. The number of the stacked semiconductor elements may be three or more.

As described above, since the element fixing resin portion 109 is formed on the outer peripheral surfaces, of the second semiconductor element 105, not including its electrode arranged side, the second semiconductor element 105 is more securely fixed. The element fixing resin portion 109 inhibits the displacement of the semiconductor element 105 especially in a surface direction and thus contributes to efficient transfer of the ultrasonic vibration to the metal wires 108 at the time of the wire bonding. Specifically, at the time of the wire bonding, the ultrasonic vibration is generally applied in the surface direction of a semiconductor element along with the application of a load (or heat as required). At this time, if a fixing force of the semiconductor element is not strong enough and thus the semiconductor element is displaced in the surface direction at the time of the application of the ultrasonic vibration, the ultrasonic vibration is absorbed and cannot be sufficiently applied, resulting in a decreased bonding force of the metal wires and deteriorated bonding reliability.

As a solution to these problems, the element fixing resin portion 109 inhibits the displacement of the semiconductor element 105 in the surface direction, and consequently, the ultrasonic wave applied at the time of the wire bonding can be efficiently transferred to the metal wires 108. The element fixing resin portions 109 has an especially high effect on the long and thin semiconductor element 105. Further, since the element fixing resin portion 109 is formed on the outer peripheral surfaces, of the semiconductor element 105, not including its electrode arranged sides of the semiconductor element 105, the electrode pads 107 are not contaminated even if the liquid resin spreads up to the top of the semiconductor element 105. Because of these reasons, it is possible to improve connectability of the metal wires 108 to the semiconductor element 105 and reliability of the connection. That is, it is possible to provide the semiconductor device 101 excellent in wire bonding performance and connection reliability.

The semiconductor device 101 according to the sixth embodiment may be combined with any of the semiconductor devices 1, 21, 31, 51, 71 according to the first, second, third, fourth, and fifth embodiments. Specifically, the element fixing resin portion 109 may be employed in combination with any of the wire fixing resin portion 11 fixing the metal wires, the insulating resin portion 41 preventing the leakage between the metal wires and between the metal wires and the semiconductor element, the filling resin portion 65 filling up the hollow portion existing under the visor-shaped overhanging portion, the buried resin portion 80 reducing the level difference on the semiconductor element, and so on. The use of the application and curing of the liquid resin can provide various effects such as the prevention of the wire sweep, the prevention of the leakage between the metal wires and the semiconductor element, the prevention of the leakage and short circuit between the metal wires, the inhibition of voids in the sealing resin layer, and the improvement in connection strength of the metal wires.

It should be noted that the present invention is not limited to the above-described embodiments but is applicable to various semiconductor devices having semiconductor elements mounted on a wiring board. Further, the above-described embodiments may be applied in combination, and the combined embodiments are also included in the present invention. Further, the embodiments of the present invention can be extended or modified within the range of the technical idea of the present invention. The extended and modified embodiments are also included in the technical scope of the present invention.

What is claimed is:

1. A semiconductor device, comprising:
a wiring board having an element mounting portion and connection pads;
a first semiconductor element, mounted on the element mounting portion of the wiring board, having first electrode pads arranged along at least one outer side of the first semiconductor element;
a second semiconductor element, stacked on the first semiconductor element, having second electrode pads arranged along at least one outer side of the second semiconductor element positioned near the outer side of the first semiconductor element;
first metal wires electrically connecting the connection pads and the first electrode pads;
second metal wires electrically connecting the connection pads and the second electrode pads, the second metal wires wiring in the same direction as the first metal wires;
a wire fixing resin portion filled between the first metal wires and the second metal wires to fix the second metal wires; and
a sealing resin layer formed on the wiring board to seal the first and second semiconductor elements together with the first and second metal wires.

2. The semiconductor device as set forth in claim 1,
wherein the wire fixing resin portion has a cured matter of liquid resin filled between the first metal wires and the second metal wires.

3. The semiconductor device as set forth in claim 1,
wherein the second semiconductor element is smaller than the first semiconductor element.

4. A semiconductor device, comprising:
a wiring board having an element mounting portion and connection pads;
a first semiconductor element, mounted on the element mounting portion of the wiring board, having first electrode pads arranged along at least one outer side of the first semiconductor element;
a second semiconductor element, stacked on the first semiconductor element, having second electrode pads arranged along at least one outer side of the second semiconductor element;
a third semiconductor element, stacked on the second semiconductor element, having third electrode pads arranged along at least one outer side of the third semiconductor element positioned near the outer side of the second semiconductor element;
first metal wires electrically connecting the connection pads and the first electrode pads;
second metal wires electrically connecting the connection pads and the second electrode pads;
third metal wires electrically connecting the connection pads and the third electrode pads, the third metal wires wiring in the same direction as the second metal wires;
a wire fixing resin portion filled between the second metal wires and the third metal wires to fix the second and third metal wires; and
a sealing resin layer formed on the wiring board to seal the first, second, and third semiconductor elements together with the first, second, and third metal wires.

5. The semiconductor device as set forth in claim 4,
wherein the wire fixing resin portion has a cured matter of liquid resin filled between the second metal wires and the third metal wires.

6. The semiconductor device as set forth in claim 4,
wherein the wire fixing resin portion is further filled in a space under the second metal wires.

7. The semiconductor device as set forth in claim 4,
wherein the wire fixing resin portion is formed inside the first semiconductor element.

8. The semiconductor device as set forth in claim 4,
wherein the third semiconductor element is smaller than the second semiconductor element.

9. The semiconductor device as set forth in claim 4,
wherein the second and third metal wires are wired in the same direction as the first metal wires, and the wire fixing resin portion is further filled in a space between the first metal wires and the second metal wires.

10. A semiconductor device, comprising:
a wiring board having an element mounting portion and connection pads;
a semiconductor element, disposed above the element mounting portion of the wiring board, having electrode pads arranged along at least one outer side of the semiconductor element;
metal wires electrically connecting the connection pads and the electrode pads;
an insulating resin portion having a cured matter of liquid resin applied to cover end portions of the metal wires connected to the semiconductor element; and
a sealing resin layer formed on the wiring board to seal the semiconductor element together with the metal wires.

11. The semiconductor device as set forth in claim 10,
wherein the insulating resin portion is formed from the end portions of the metal wires to extend along the metal wires.

12. The semiconductor device as set forth in claim 10,
wherein the semiconductor element is stacked on another semiconductor element which is mounted on the element mounting portion of the wiring board, and is smaller than the another semiconductor element.

13. A semiconductor device, comprising:
a wiring board having an element mounting portion and connection pads;
a first semiconductor element, mounted on the element mounting portion of the wiring board, having first electrode pads arranged along at least one outer side of the first semiconductor element;
a second semiconductor element, stacked on the first semiconductor element, having second electrode pads arranged along at least one outer side of the second semiconductor element, at least part of an outer peripheral portion of the second semiconductor element protruding in a visor shape;
first metal wires electrically connecting the connection pads and the first electrode pads;
second metal wires electrically connecting the connection pads and the second electrode pads;
a filling resin portion having a cured matter of liquid resin which is filled in a hollow portion existing under the visor-shaped protruding portion of the second semiconductor element; and
a sealing resin layer formed on the wiring board to seal the first and second semiconductor elements together with the first and second metal wires.

14. The semiconductor device as set forth in claim 13,
wherein the liquid resin is filled in the hollow portion by applying from above the second metal wires which is wired to cover the hollow portion.

15. The semiconductor device as set forth in claim 13, further comprising:
a third semiconductor element, stacked on the second semiconductor element, having third electrode pads arranged along at least one outer side of the third semiconductor element, the third semiconductor element being smaller than the second semiconductor element;
a buried resin portion having a cured matter of liquid resin applied on a surface region of the second semiconductor element excluding a region on which the third semiconductor element is stacked; and
third metal wires electrically connecting the connection pads and the third electrode pads.

16. A semiconductor element, comprising:
a wiring board having an element mounting portion and connection pads;
a first semiconductor element, mounted on the element mounting portion of the wiring board, having first electrode pads arranged along at least one outer side of the first semiconductor element;
a second semiconductor element, stacked on the first semiconductor element, having second electrode pads arranged along at least one outer side of the second semiconductor element, the second semiconductor element being smaller than the first semiconductor element;
a buried resin portion having a cured matter of liquid resin applied on a surface region of the first semiconductor element excluding a region on which the second semiconductor element is stacked;
first metal wires electrically connecting the connection pads and the first electrode pads;
second metal wires electrically connecting the connection pads and the second electrode pads; and
a sealing resin layer formed on the wiring board to seal the first and second semiconductor elements together with the first and second metal wires.

17. The semiconductor device as set forth in claim 16,
wherein the buried resin portion is formed on the surface region of the first semiconductor element to eliminate difference in level on the first semiconductor element based on the second semiconductor element.

18. A semiconductor device, comprising:
a wiring board having an element mounting portion and connection pads;
a first semiconductor element, bonded on the element mounting portion of the wiring board via a first adhesive layer, having first electrode pads arranged along at least one outer side of the first semiconductor element;
a second semiconductor element, bonded on the first semiconductor element via a second adhesive layer, having second electrode pads arranged along at least one outer side of the second semiconductor element;
an element fixing resin portion formed along an outer peripheral portion including an outer side of the second semiconductor element excluding the outer side along which the second electrode pads is arranged, to fix the second semiconductor element;
first metal wires electrically connecting the connection pads and the first electrode pads;
second metal wires electrically connecting the connection pads and the second electrode pads;
a sealing resin layer formed on the wiring board to seal the first and second semiconductor elements together with the first and second metal wires.

19. The semiconductor device as set forth in claim 18,
wherein the element fixing resin portion has a cured matter of liquid resin applied along the outer peripheral portion of the second semiconductor element.

20. The semiconductor device as set forth in claim 18,
wherein the second semiconductor element is smaller than the first semiconductor element.
